(19) United States
(12) Patent Application Publication
(10) Pub. No.: US 2008/0112191 A1
(43) Pub. Date: May 15, 2008

(54) Supporting frame and supporting frame assembly for a backlight module

(76) Inventors: Chia-Huang Wu, Taichung City (TW); Shih-Jung Lai, Fongyuan City (TW)

Correspondence Address: ROSENBERG, KLEIN & LEE, 3458 ELLICOTT CENTER DRIVE-SUITE 101, ELLICOTT CITY, MD, 21043, US

(21) Appl. No.: 11/599,317

(22) Filed: Nov. 15, 2006

(51) Int. Cl. H05K 5/00

(52) U.S. Cl. 362/634; 361/759

(57) ABSTRACT

A supporting frame has a frame body and at least one connecting post. The frame body has a connecting face and an edge. The at least one connecting post is formed on and extends from the connecting face at the edge. Each connecting post is hollow and conical and has an enlarged end, a reduced end and at least one slit. The enlarged end has a diameter and is formed on the connecting face of the frame body. The reduced end has a diameter smaller than that of the enlarged end and is away from the connecting face of the frame body. The at least one slit is longitudinally formed in the connecting post. Accordingly, the supporting frame can be easily and precisely combined with a circuit board.

### BACKGROUND OF THE INVENTION

1. Field of the Invention

The present invention relates to a supporting frame, and more particularly to a supporting frame for a backlight module and that is easily and conveniently assembled with a circuit board.

2. Description of Related Art

With reference to FIGS. 6 and 7, a conventional supporting frame assembly for a backlight module of a liquid crystal display (LCD) in accordance with the present invention comprises a supporting frame (60) and a circuit board (70). The supporting frame (60) comprises a frame body and at least one connecting post (61). The at least one connecting post (61) is formed on and extends from the frame body and is solid and cylindrical. Each connecting post (61) corresponds to and engages with a connecting hole (71) defined in the circuit board (70) to connect the supporting frame (60) and the circuit board (70) together.

Generally, the diameter of the connecting posts (61) is substantially equal to but slightly larger than that of the connecting holes (71) to make the connecting posts (61) being pressed into the connecting holes (71) so as to securely combine the supporting frame (60) and the circuit board (70) together. However, because the diameter of the connecting posts (61) is substantially equal to that of the connecting holes (71), precise alignment between the connecting posts (61) and the connecting holes (71) is necessary for assembling the supporting frame (60) and the circuit board (70). Therefore, to combine the conventional supporting frame assembly is difficult and laborious.

In addition, the conventional supporting frame (60) is made with a mold injecting process, but the connecting posts (61) are easily deformed or displaced to cause the connecting posts (61) leaving from a desired diameter magnitude or location on the supporting frame (60). Consequently, the combination between the supporting frame (60) and the circuit board (70) may fail.

Moreover, the conventional connecting posts (61) on the supporting frame (60) are solid cylinders. If the height of the connecting posts (61) is prolonged to enhance the combination of the supporting frame (60) and the circuit board (70), but the prolonged connecting posts (61) are easily broken during the assembling process of the conventional supporting frame assembly. If the height of the connecting posts (61) are reduced to keep the connecting posts (61) from being broken, but the combining strength between the shorter connecting posts (61) and the connecting holes (71) is reduced so that the circuit board (70) is easily detached from the supporting frame (60).

To overcome the shortcomings, the present invention tends to provide a supporting frame assembly to mitigate or obviate the aforementioned problems.

### SUMMARY OF THE INVENTION

The main objective of the invention is to provide a supporting frame for a backlight module and that is easily and precisely combined with a circuit board. The supporting frame has a frame body and at least one connecting post. The frame body has a connecting face and an edge. The at least one connecting post is formed on and extends from the connecting face at the edge. Each connecting post is hollow and conical and has an enlarged end, a reduced end and at least one slit. The enlarged end has a diameter and is formed on the connecting face of the frame body. The reduced end has a diameter smaller than that of the enlarged end and is away from the connecting face of the frame body. The at least one slit is longitudinally formed in the connecting post.

Other objects, advantages and novel features of the invention will become more apparent from the following detailed description when taken in conjunction with the accompanying drawings.

### BRIEF DESCRIPTION OF THE DRAWINGS

FIG. 1 is an exploded perspective view of a first embodiment of a supporting frame assembly for a backlight module in accordance with the present invention;

FIG. 2 is an enlarged perspective view of a connecting post on the supporting frame of the supporting frame assembly in FIG. 1;

FIG. 3 is an operational side plan view in cross section of the supporting frame assembly in FIG. 1 showing the assembling process of the supporting frame and the circuit board;

FIG. 4 is an exploded perspective view of a second embodiment of a supporting frame assembly for a backlight module in accordance with the present invention;

FIG. 5 is a side plan view in partial section of the supporting frame assembly in FIG. 4;

FIG. 6 is an exploded perspective view of a conventional supporting frame assembly for a backlight module in accordance with the prior art; and

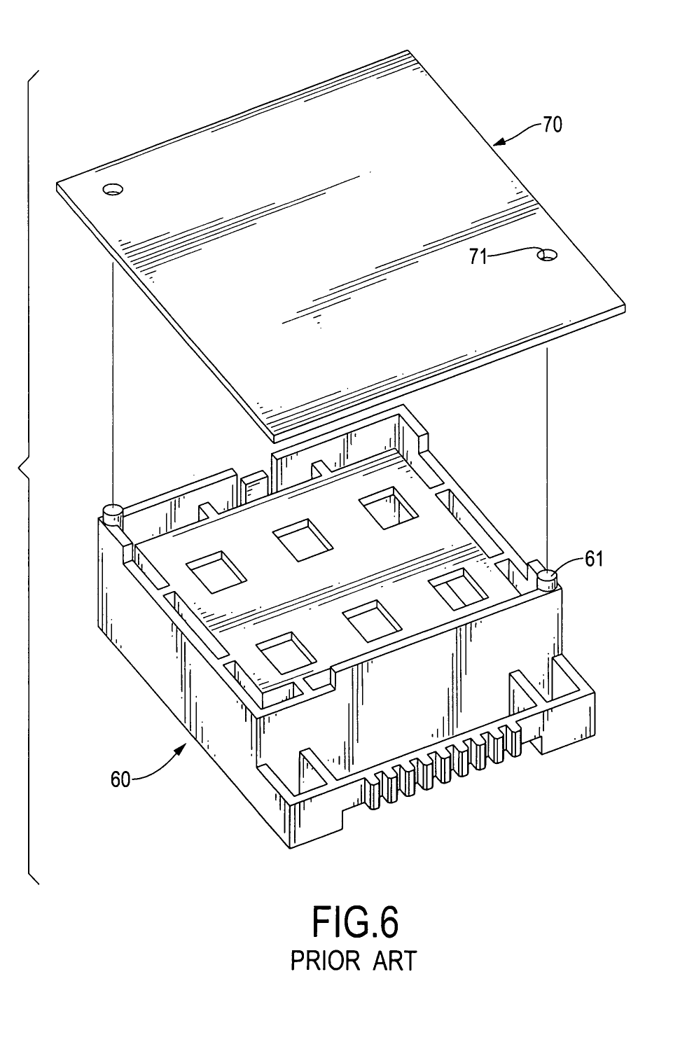

FIG. 7 is an enlarged perspective view of a connecting post of the conventional supporting frame assembly in FIG. 8.

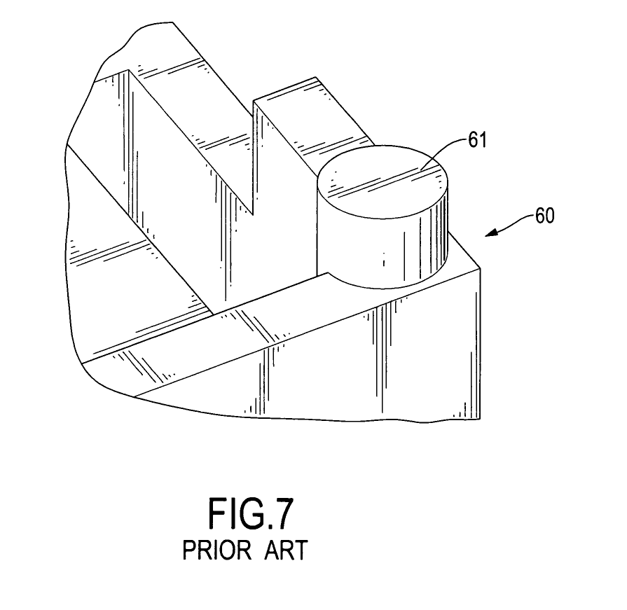

### DETAILED DESCRIPTION OF PREFERRED EMBODIMENT

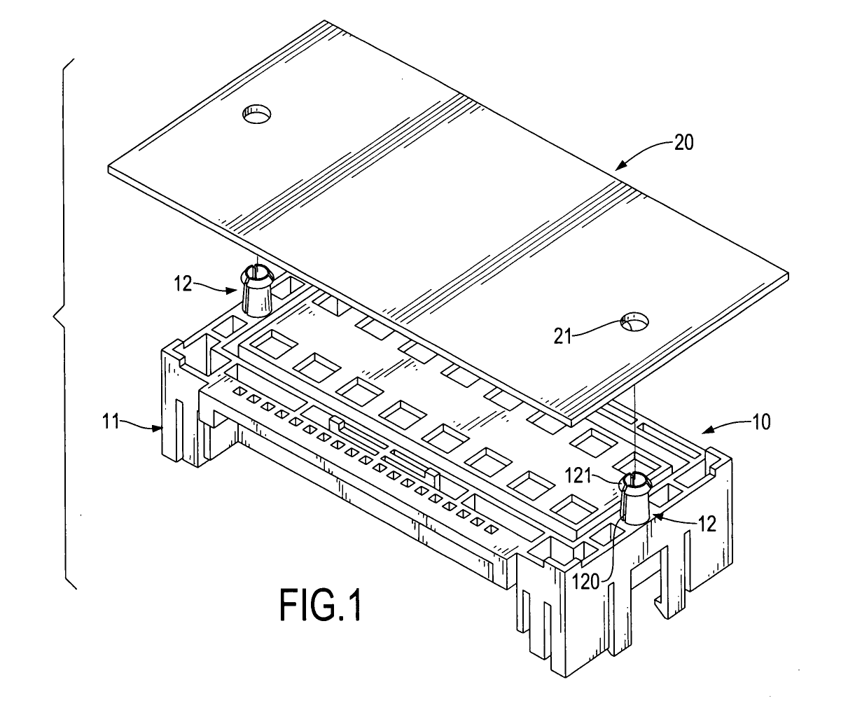

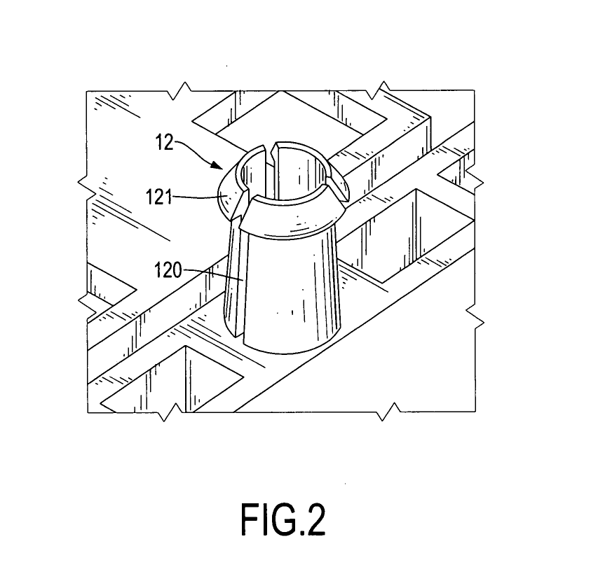

With reference to FIGS. 1 and 2, a supporting frame assembly for a backlight module in accordance with the present invention comprises a supporting frame (10) and a circuit board (20). The supporting frame (10) comprises a frame body (11) and at least one connecting post (12), preferably two connecting posts (12). The frame body (11) comprises a connecting face and an edge. The frame body (11) has a rectangular cross shape, and the edge of the frame body (11) comprises two long sides with a length and two short sides with a length shorter than that of the long sides.

The connecting posts (12) are formed on and extend from the connecting face and near the edge of the frame body (11). In a preferred embodiment, two connecting posts (12) are respectively formed on the short sides of the frame body (11). Each connecting post (12) is hollow and conical and comprises an enlarged end, a reduced end, an enlarged head (121) and at least one slit (120). The enlarged end has a diameter and is formed on the connecting face of the frame body (11). The reduced end has a diameter smaller than that of the enlarged end and is away from the connecting face of the frame body (11). The enlarged head (121) is formed around the reduced end of the connecting post (12). The at least one slit (120) is longitudinally formed in the connecting post (12). In the preferred embodiment, three slits (120) are evenly and longitudinally formed in each connecting post (12) and extend from the enlarged head (121) toward the enlarged end.

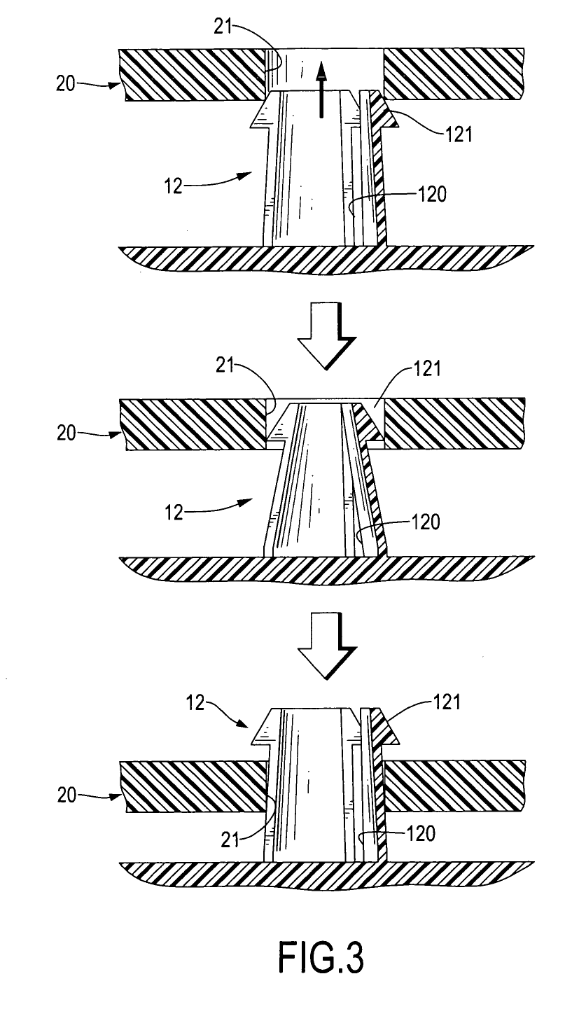

The circuit board (20) is attached to the connecting face of the frame body (11) of the supporting frame (10) and comprises at least one connecting hole (21), preferably two connecting holes (21). The connecting holes (21) are defined through the circuit board (20), correspond respectively to the connecting posts (12) on the supporting frame (10). With further reference to FIG. 3, each connecting hole (21) has a diameter smaller than that of the enlarged end of a corresponding connecting post (12) and larger than that of the reduced end of the corresponding post (12).

With reference to FIGS. 1 and 3, during a process of assembling the circuit board (20) onto the supporting frame (10), the connecting posts (12) are inserted into the connecting holes (21) from the enlarged heads (121). With the arrangements of the slits (120), the connecting posts (12) are resilient such that the connecting posts (12) can be compressed to allow the connecting posts (12) to be inserted into and extend through the connecting holes (21). Because the enlarged ends of the connecting posts (12) have a diameter larger than that of the connecting holes (21), the resilient connecting posts (12) will tightly press against the connecting holes (21) to make the circuit board (20) securely combine with the supporting frame (10). In addition, the arrangements of the enlarged heads (121) on the connecting posts (12), the circuit board (20) will not escape from the supporting frame (10) even when an external force applied to the supporting frame assembly.

With such an arrangement, because the connecting posts (12) are hollow, conical and resilient, the connecting posts (12) can securely and precisely engage with the connecting holes (21) even when the diameters or locations of the connecting posts (12) are not at desired conditions. To precisely align the connecting posts (12) on the supporting frame (10) with the connecting holes (21) in the circuit board (20) is unnecessary, such that to assemble the supporting frame assembly is easy and conveniently.

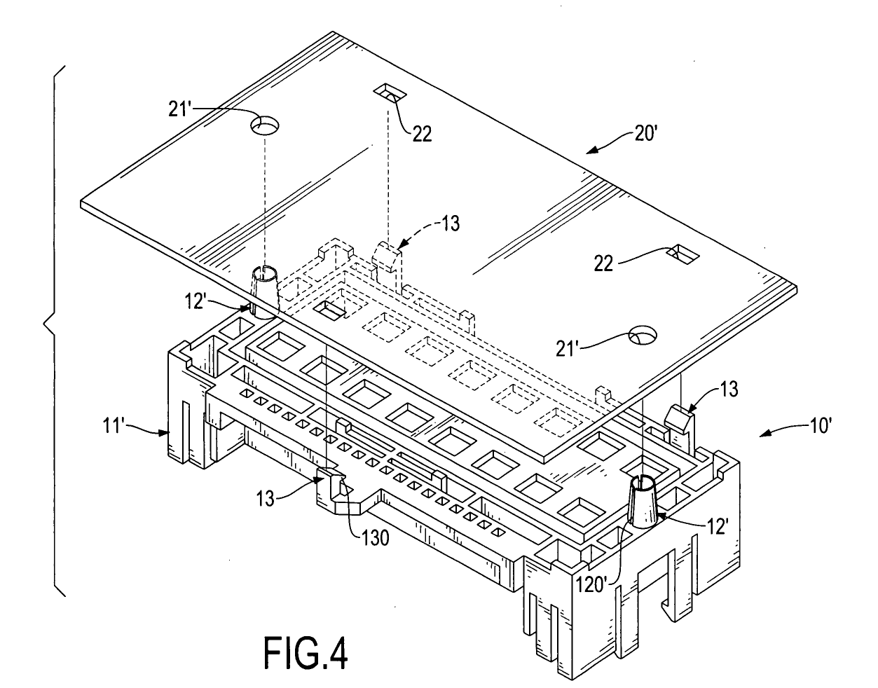

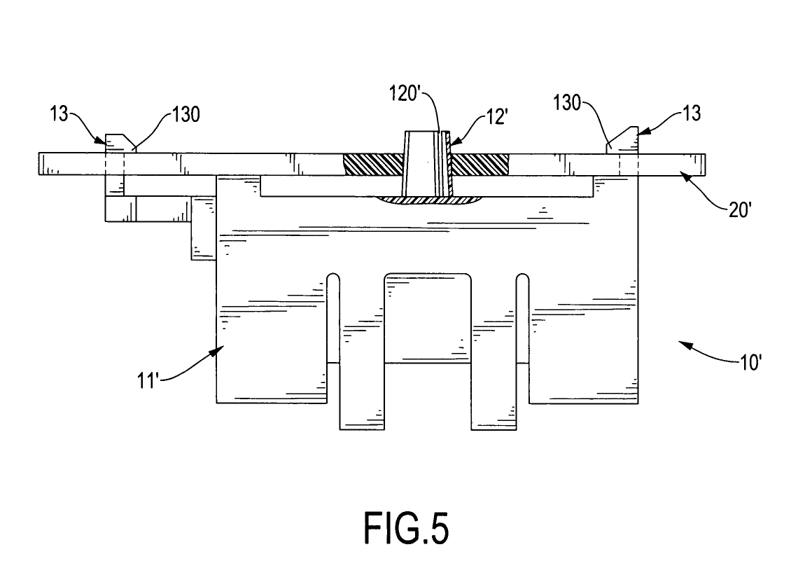

With reference to FIGS. 4 and 5, a second embodiment of a supporting frame assembly in accordance with the present invention comprises a supporting frame (10′) and a circuit board (20′). The supporting frame (10′) comprises a frame body (11′), at least one connecting post (12′) and at least one hook (13). The frame body (11′) comprises a connecting face and an edge. The edge of the frame body (11′) comprises two long sides with a length and two short sides with a length shorter than that of the long sides. The connecting posts (12′) are substantially same as that in the first embodiment, except that the enlarged heads are kept free from the connecting posts (12′). The at least one hook (13) is formed on and extends from the connecting face of the frame body (11′) and is located away from the connecting posts (12′). In a preferred embodiment, the supporting frame (10′) comprises three hooks (13) respectively formed on the long sides of the frame body (11′). Wherein, two of the hooks (13) are formed on one of the long sides of the frame body (11′) respectively near the short sides, and one hook (13) is formed on a middle of the other long side. Each hook (13) has an engaging head (130) formed on a free end of the hook (13).

The circuit board (20′) comprises at least one connecting hole (21′) and at least one engaging hole (22) defined through the circuit board (20′). The at least one engaging hole (22) respectively corresponds to and engages with the at least one hook (13) on the supporting frame (10′). In the preferred embodiment, the circuit board (20′) has three engaging holes (22) respectively corresponding to and engaging with the hooks (13) on the supporting frame (10′).

With the engagements between the hooks (13) on the supporting frame (10′) and the engaging holes (22) in the circuit board (20′), the circuit board (20′) is securely attached and held on the supporting frame (10′) in stable.

The supporting frame assembly in accordance with the present invention has advantages as follows:

1. Because the connecting posts (12,12′) on the supporting frame (10,10′) are hollow, conical and resilient, a guiding and a central positioning effects are provided by the connecting posts (12,12′) to assemble the circuit board (20,20′) onto the supporting frame (10,10′). In addition, the connecting posts (12,12′) can securely engage and fit with the connecting holes (21,21′) in different diameters of different circuits (20,20′), the structure of supporting frame (10,10′) can be modularized. Accordingly, to assemble the supporting frame assembly is convenient and versatile, and the cost for manufacturing the supporting frame (10,10′) is reduced.

2. The three hooks (13) on the supporting frame (10′) can provide an even and excellent support to the circuit board (20′) due to the principle of that three points always construct a plane.

Even though numerous characteristics and advantages of the present invention have been set forth in the foregoing description, together with details of the structure and function of the invention, the disclosure is illustrative only, and changes may be made in detail, especially in matters of shape, size, and arrangement of parts within the principles of the invention to the full extent indicated by the broad general meaning of the terms in which the appended claims are expressed.

What is claimed is:

1. A supporting frame for a backlight module comprising:
a frame body comprising a connecting face and an edge; and
at least one connecting post formed on and extending from the connecting face and near the edge and each one of the connecting post being hollow and conical and comprising:
an enlarged end with a first diameter, the enlarged end being formed on the connecting face of the frame body;
a reduced end with a second diameter smaller than the first diameter, the reduced end being away from the connecting face of the frame body; and
at least one slit longitudinally formed in the connecting post.

2. The supporting frame as claimed in claim 1, wherein each of the connecting post further has an enlarged head formed around the reduced end of the connecting post.

3. The supporting frame as claimed in claim 1 further comprising at least one hook formed on and extending from the connecting face of the frame body and located away from the connecting post, and each of the hooks comprising an engaging head formed on a free end of the hook.

4. The supporting frame as claimed in claim 2 further comprising at least one hook formed on and extending from the connecting face of the frame body and located away from the connecting post, and each of the hooks comprising an engaging head formed on a free end of the hook.

5. The supporting frame as claimed in claim 1, wherein the frame body has a rectangular cross shape and the edge of the frame body comprises two long sides with a length and two short sides with a length shorter than that of the long sides; and
the supporting frame comprises two connecting posts respectively formed on the short sides of the frame body.

6. The supporting frame as claimed in claim 2, wherein the frame body has a rectangular cross shape and the edge of the frame body comprises two long sides with a length and two short sides with a length shorter than that of the long sides; and
the supporting frame comprises two connecting posts respectively formed on the short sides of the frame body.

7. The supporting frame as claimed in claim 3, wherein the frame body has a rectangular cross shape and the edge of the frame body comprises two long sides with a length and two short sides with a length shorter than that of the long sides; and
the supporting frame comprises two connecting posts respectively formed on the short sides of the frame body.

8. The supporting frame as claimed in claim 4, wherein the frame body has a rectangular cross shape and the edge of the frame body comprises two long sides with a length and two short sides with a length shorter than that of the long sides; and
the supporting frame comprises two connecting posts respectively formed on the short sides of the frame body.

9. The supporting frame as claimed in claim 7, wherein the supporting frame comprises three hooks formed on the frame body respectively at the long sides of the frame body.

10. The supporting frame as claimed in claim 8, wherein the supporting frame comprises three hooks formed on the frame body respectively at the long sides of the frame body.

11. The supporting frame as claimed in claim 1, wherein each one of the at least one connecting post has three slits evenly and longitudinally defined in the connecting post.

12. A supporting frame assembly for a backlight module comprising:
a supporting frame comprising
a frame body comprising a connecting face and an edge; and
at least one connecting post formed on and extending from the connecting face at the edge and each one of the at least one connecting post being hollow and conical and comprising
an enlarged end with a diameter formed on the connecting face of the frame body;
a reduced end with a diameter smaller than that of the enlarged end and away from the connecting face of the frame body; and
at least one slit longitudinally formed in the connecting post; and
a circuit board attached to the connecting face of the frame body of the supporting frame and comprising
at least one connecting hole defined through the circuit board, corresponding respectively to the at least one connecting post and having a diameter smaller than that of the enlarged end of a corresponding connecting post and larger than that of the reduced end of the corresponding post.

13. The supporting frame assembly as claimed in claim 12, wherein each one of the at least one connecting post further has an enlarged head formed around the reduced end of the connecting post.

14. The supporting frame assembly as claimed in claim 12, wherein
the supporting frame further comprises at least one hook formed on and extending from the connecting face of the frame body and located away from the at least one connecting post, and each one of the at least one hook comprising an engaging head formed on a free end of the hook; and
the circuit board further comprises at least one engaging hole defined through the circuit board and respectively corresponding to and engaging with the at least one hook on the supporting frame.

15. The supporting frame assembly as claimed in claim 13, wherein
the supporting frame further comprises at least one hook formed on and extending from the connecting face of the frame body and located away from the at least one connecting post, and each one of the at least one hook comprising an engaging head formed on a free end of the hook; and
the circuit board further comprises at least one engaging hole defined through the circuit board and respectively corresponding to and engaging with the at least one hook on the supporting frame.

16. The supporting frame assembly as claimed in claim 12, wherein the frame body has a rectangular cross shape and the edge of the frame body comprises two long sides with a length and two short sides with a length shorter than that of the long sides; and
the supporting frame comprises two connecting posts respectively formed on the short sides of the frame body.

17. The supporting frame assembly as claimed in claim 15, wherein the frame body has a rectangular cross shape and the edge of the frame body comprises two long sides with a length and two short sides with a length shorter than that of the long sides; and
the supporting frame comprises two connecting posts respectively formed on the short sides of the frame body.

18. The supporting frame assembly as claimed in claim 16, wherein the frame body has a rectangular cross shape and the edge of the frame body comprises two long sides with a length and two short sides with a length shorter than that of the long sides; and
the supporting frame comprises two connecting posts respectively formed on the short sides of the frame body.

19. The supporting frame assembly as claimed in claim 17, wherein the supporting frame comprises three hooks formed on the frame body respectively at the long sides of the frame body; and
the circuit board has three engaging holes respectively corresponding to and engaging with the hooks on the supporting frame.

20. The supporting frame assembly as claimed in claim 18, wherein the supporting frame comprises three hooks formed on the frame body respectively at the long sides of the frame body; and
the circuit board has three engaging holes respectively corresponding to and engaging with the hooks on the supporting frame.
